(19) United States
(12) Patent Application Publication
(10) Pub. No.: US 2018/0022103 A1
(43) Pub. Date: Jan. 25, 2018

(54) PRINTHEADS WITH EPROM CELLS HAVING ETCHED MULTI-METAL FLOATING GATES

(71) Applicant: HEWLETT-PACKARD DEVELOPMENT COMPANY, L.P., Houston, TX (US)

(72) Inventors: Ning GE, Palo Alto, CA (US); Zhiyong LI, Singapore (SG); Ser Chia KOH, Singapore (SG); Chaw Sing HO, Singapore (SG)

(73) Assignee: HEWLETT-PACKARD DEVELOPMENT COMPANY, L.P., Houston, TX (US)

(21) Appl. No.: 15/546,085

(22) PCT Filed: Apr. 10, 2015
(86) PCT No.: PCT/US2015/025424

§ 371 Date: Jul. 25, 2017

(51) Int. Cl. B41J 2/175; H01L 27/11521

(52) U.S. Cl. CPC B41J 2/17546; H01L 27/11521; H01L 29/4916

(57) ABSTRACT

In one example in accordance with the present disclosure a printhead with a number of EPROM cells is described. The printhead deposits fluid onto a print medium. The printhead also includes a number of EPROM cells. Each EPROM cell includes a substrate having a source and a drain disposed therein, a floating gate separated from the substrate by a first dielectric layer. The floating gate includes a multi-metal layer that is a metal etched layer. Each EPROM cell also includes a control gate separated from the multi-metal layer of the floating gate by a second dielectric layer.

### BACKGROUND

A memory system may be used to store data. In some examples, imaging devices, such as printheads may include memory to store information relating to printer cartridge identification, security information, and authentication information, among other types of information.

### BRIEF DESCRIPTION OF THE DRAWINGS

The accompanying drawings illustrate various examples of the principles described herein and are a part of the specification. The illustrated examples do not limit the scope of the claims,

FIG. 1 is a diagram of a printing system according to one example of the principles described herein.

FIG. 2 is a block diagram of a printer cartridge that uses a printhead with a number of erasable programmable read only memory (EPROM) cells having etched multi-metal floating gates according to one example of the principles described herein.

FIG. 3A is a diagram of a printer cartridge with a number of EPROM cells according to one example of the principles described herein.

FIG. 3B is a cross sectional diagram of a printer cartridge with a number of EPROM cells having etched multi-metal floating gates according to one example of the principles described herein.

FIG. 3C is a cross sectional diagram of a printhead with a number of EPROM cells having etched multi-metal floating gates according to one example of the principles described herein.

FIG. 4A is a circuit diagram of an EPROM cell having etched multi-metal floating gates according to one example of the principles described herein.

FIG. 4B is a cross-sectional view of an EPROM cell having etched multi-metal floating gates before etching according to one example of the principles described herein.

FIG. 4C is a cross-sectional view of an EPROM cell having etched multi-metal floating gates after etching according to one example of the principles described herein.

FIG. 5 is a cross-sectional view of a printhead including an EPROM cell having etched multi-metal floating gates and a firing resistor according to one example of the principles described herein.

Throughout the drawings, identical reference numbers designate similar, but not necessarily identical, elements.

### DETAILED DESCRIPTION

Memory devices are used to store information for a printer cartridge. Printer cartridges include memory to store information related to the operation of the printhead. For example, a printhead may include memory to store information related 1) to the printhead; 2) to fluid, such as ink, used by the printhead; or 3) to the use and maintenance of the printhead. Other examples of information that may be stored on a printhead include information relating to 1) a fluid supply, 2) fluid identification information, 3) fluid characterization information, and 4) fluid usage data, among other types of fluid or imaging device related data. More examples of information that may be stored include identification information, serial numbers, security information, feature information, Anti-Counterfeiting (ACF) information, among other types of information. While memory usage on printheads is desirable, changing circumstances may reduce their efficacy in storing information.

For example, an increasing trend in counterfeiting may lead to current memory devices being too small to contain sufficient anti-counterfeiting information and security and authentication information. Additionally, with loyalty customer reward programs, new business models and other customer relation management programs through cloud-printing and other printing architectures, additional market data, customer appreciation value information, encryption information, and other types of information on the rise, a manufacturer may desire to store more information on a memory device of a printer cartridge.

Moreover, as new technologies develop, circuit space is at a premium. Accordingly, it may be desirable for the greater amounts of data storage to occupy less space within a device. Erasable programmable read only memory (EPROM) cells may be used for their simple construction, non-volatility, and efficient storage of data. EPROM arrays include a conductive grid of columns and rows. EPROM cells located at intersections of rows and columns have two gates that are separated from each other by a dielectric layer. One of the gates is called a floating gate and the other is called a control gate. A logical value may be represented by either allowing current to flow through, or preventing current from flowing through the EPROM cell. In other words, the logical value of an EPROM cell may be determined by the resistance of the EPROM cell. Such a resistance is dependent upon the voltage at the floating gate of the EPROM cell. While EPROM cells may serve as beneficial memory storage devices, their use presents a number of complications.

For example, printheads are formed by depositing layers of material on a substrate surface. As an EPROM cell includes two gates, multiple additional layers of material are used to form these EPROM cells on printheads. The additional layers increase the thickness of the printhead and overall size of the printhead. Moreover, as will be described below, in order to generate an EPROM that is easily read from and written to, the dielectric layer, i.e., the layer between a control gate and a floating gate of the EPROM cell, can be rather thick, which thickness further increases the size and inefficiency of EPROM as a memory storage device.

Accordingly, the present disclosure describes a printhead with EPROM cells that alleviate these and other complications. For example, an EPROM cell may be formed that uses a floating gate having multiple layers at least one of which is metal etched to expose another layer. More specifically, a floating gate of the EPROM cell may be formed of two metallic layers. One of the metallic layers may be of one material and the second layer may be of a different material. Via metal etching a portion of the uppermost layer is removed to expose the underlying layer. From the underlying layer a dielectric layer between the floating gate and the control gate is grown. Using such a process to expose the underlying layer allows a thinner dielectric layer to be formed on top of the floating gate. The thinner dielectric layer therefore allows for a thinner EPROM cell to be formed while maintaining sufficient capacitance for effective memory storage.

More specifically, the present disclosure describes a printhead with a number of erasable programmable read only memory (EPROM) cells having etched multi-metal floating gates. The printhead includes a number of nozzles to deposit an amount of fluid onto a print medium. Each nozzle includes a firing chamber to hold the amount of fluid, an opening to dispense the amount of fluid onto the print medium, and an ejector to eject the amount of fluid through the opening. The printhead also includes a number of EPROM cells. Each EPROM cell includes a substrate having a source and a drain disposed therein and a floating gate separated from the substrate by a first dielectric layer. The floating gate includes at least an etched multi-metal layer. Each EPROM cell also includes a control gate separated from the etched multi-metal layer of the floating gate by a second dielectric layer.

The present disclosure also describes a printer cartridge having a number of erasable programmable read only memory (EPROM) cells having etched multi-metal floating gates. The cartridge includes a fluid supply and a printhead to deposit fluid from the fluid supply onto a print medium. The printhead includes a number of EPROM cells. Each EPROM cell includes a substrate having a source and a drain disposed therein, and a floating gate separated from the substrate by a first dielectric layer. The floating gate includes a polysilicon layer separated from the substrate by a first dielectric layer and an etched multi-metal layer separated from the polysilicon layer by a third dielectric layer. The etched multi-metal layer contacts the polysilicon layer through a gap in the third dielectric layer. Each EPROM cell also includes a control gate separated from the substrate by a second dielectric layer. The second dielectric layer is formed from oxidation of at least one sub-layer of the etched multi-metal layer.

A printer cartridge and a printhead that utilize EPROM cells having etched multi-metal floating gates may provide memory storage to a printhead in the form of EPROM memory, while reducing the number and thickness of layers used to form the printhead. Moreover, the layers and processes used to form the EPROM may correspond to layers used to form other components, such as firing resistors and memristors of the printhead. Accordingly, a set number of layers may be co-utilized to form the EPROM memory cells.

As used in the present specification and in the appended claims, the term “printer cartridge” may refer to a device used in the ejection of ink, or other fluid, onto a print medium. in general, a printer cartridge may be a fluidic ejection device that dispenses fluid such as ink, wax, polymers, or other fluids. A printer cartridge may include a printhead. hi some examples, a printhead may be used in printers, graphic plotters, copiers, and facsimile machines. In these examples, a printhead may eject ink, or another fluid, onto a medium such as paper to form a desired image or a desired three-dimensional geometry.

Accordingly, as used in the present specification and in the appended claims, the term “printer” is meant to be understood broadly as any device capable of selectively placing a fluid onto a print medium. In one example the printer is an inkjet printer, In another example, the printer is a three-dimensional printer. In yet another example, the printer is a digital titration device.

Still further, as used in the present specification and in the appended claims, the term “fluid” is meant to be understood broadly as any substance that continually deforms under an applied shear stress. In one example, a fluid may be a pharmaceutical. In another example, the fluid may be an ink. In another example, the fluid may be a liquid.

Still further, as used in the present specification and in the appended claims, the term “print medium” is meant to be understood broadly as any surface onto which a fluid ejected from a nozzle of a printer cartridge may be deposited. In one example, the print medium may be paper. In another example, the print medium may be an edible substrate. In yet another example, the print medium may be a medicinal pill.

Still further, as used in the present specification and in the appended claims, the term “memristor” may refer to a passive two-terminal circuit element that maintains a functional relationship between the time integral of current, and the time integral of voltage.

Still further, as used in the present specification and in the appended claims, the term “etched multi-metal floating gate” may refer to a floating gate having multiple metallic layers, at least one of the layers being etched to expose another layer.

For example, using a metal etch process a top layer of material, such as an aluminum copper alloy may be etched to expose an underlying layer, such as a tantalum aluminum alloy in which the etching process does not impact the underlying layer.

Yet further, as used in the present specification and in the appended claims, “a”, “an”, and “the” are intended to include the plural forms as well as the singular forms, unless the context clearly indicates otherwise.

Yet further, as used in the present specification and in the appended claims, the term “a number of” or similar language may include any positive number including I to infinity; zero not being a number, but the absence of a number.

In the following description, for purposes of explanation, numerous specific details are set forth in order to provide a thorough understanding of the present systems and methods. It will be apparent, however, to one skilled in the art that the present apparatus, systems, and methods may be practiced without these specific details. Reference in the specification to “an example” or similar language means that a particular feature, structure, or characteristic described is included in at least that one example, but riot necessarily in other examples.

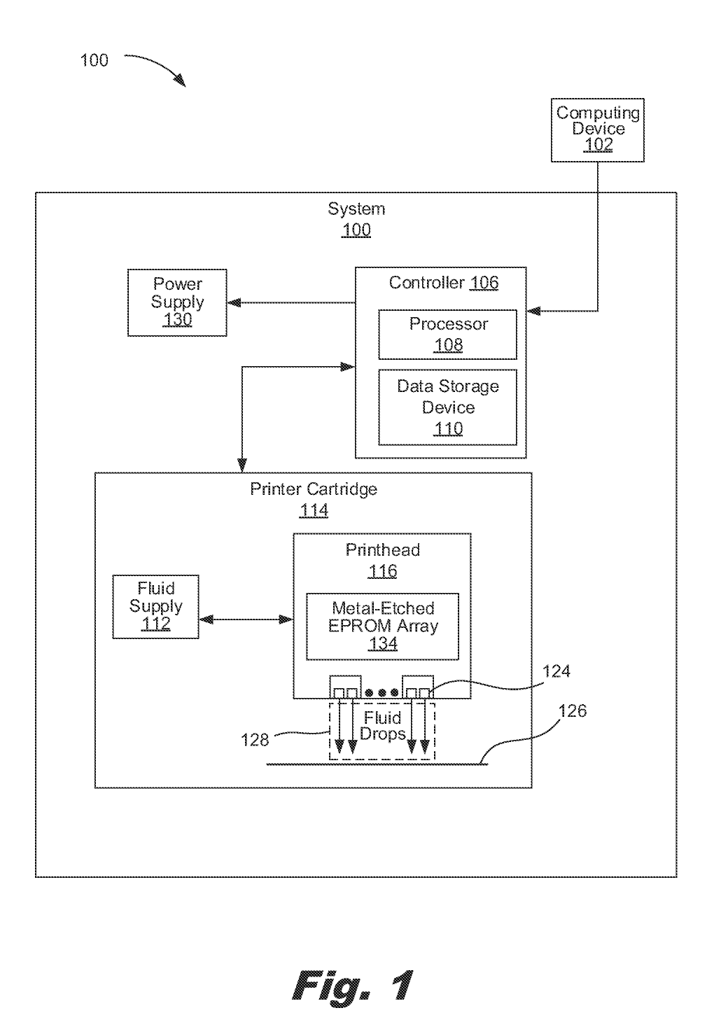

Turning now to the figures, FIG. 1 is a diagram of a printing system (100) with a printer cartridge (114) and printhead (116) according to one example of the principles described herein. In some examples, the printing system (100) may be included on a printer. The system (100) includes an interface with a computing device (102). The interface enables the system (100) and specifically the processor (108) to interface with various hardware elements, such as the computing device (102), external and internal to the system (100). Other examples of external devices include external storage devices, network devices such as servers, switches, routers, and client devices among other types of external devices.

In general, the computing device (102) may be any source from which the system (100) may receive data describing a job to be executed by the controller (106) in order to eject fluid onto the print medium (126). For example, via the interface, the controller (106) receives data from the computing device (102) and temporarily stores the data in the data storage device (110). Data may be sent to the controller (106) along an electronic, infrared, optical, or other information transfer path. The data may represent a document and/or file to be printed. As such, data forms a job for and includes job commands and/or command parameters.

A controller (106) includes a processor (108), a data storage device (110), and other electronics for communicating with and controlling the printhead (116). The controller (106) receives data from the computing device (102) and temporarily stores data in the data storage device (110).

The controller (106) controls the printhead (116) in ejecting fluid from the nozzles (124). For example, the controller (106) defines a pattern of ejected fluid drops that form characters, symbols, and/or other graphics or images on the print medium (126). The pattern of ejected fluid drops is determined by the print job commands and/or command parameters received from the computing device (102). The controller (106) may be an application specific integrated circuit (ASIC), on a printer for example, to determine the level of fluid in the printhead (116) based on resistance values of EPROM cells integrated on the printhead (116). The ASIC may include a current source and an analog to digital converter (ADC). The ASIC converts a voltage present at the current source to determine a resistance of an EPROM cell, and then determine a corresponding digital resistance value through the ADC. Computer readable program code, executed through executable instructions enables the resistance determination and the subsequent digital conversion through the ADC.

The processor (108) may include the hardware architecture to retrieve executable code from the data storage device (110) and execute the executable code. The executable code may, when executed by he processor (108), cause the processor (108) to implement at least the functionality of ejecting fluid onto the print medium (126). The executable code may also, when executed by the processor (108), cause the processor (108) to implement the functionality of providing instructions to the power supply (130) such that the power supply (130) provides power to the components of the system (100).

The data storage device (110) may store data such as executable program code that is executed by the processor (108) or other processing device. The data storage device (110) may specifically store computer code representing a number of applications that the processor (108) executes to implement at least the functionality described herein.

The data storage device (110) may include various types of memory modules, including volatile and nonvolatile memory. For example, the data storage device (110) of the present example includes Random Access Memory (RAM), Read Only Memory (ROM), and Hard Disk Drive (HDD) memory. Many other types of memory may also be utilized, and the present specification contemplates the use of many varying type(s) of memory in the data storage device (110) as may suit a particular application of the principles described herein. In certain examples, different types of memory in the data storage device (110) may be used for different data storage needs. For example, in certain examples the processor (108) may boot from Read Only Memory (ROM), maintain nonvolatile storage in the Hard Disk Drive (HDD) memory, and execute program code stored in Random Access Memory (RAM).

Generally, the data storage device (110) may include a computer readable medium, a computer readable storage medium, or a non-transitory computer readable medium, among others. For example, the data storage device (110) may be an electronic, magnetic, optical, electromagnetic, infrared, or semiconductor system, apparatus, or device, or any suitable combination of the foregoing. More specific examples of the computer readable storage medium may include, for example, the following: an electrical connection having a number of wires, a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store computer usable program code for use by or in connection with an instruction execution system, apparatus, or device. In another example, a computer readable storage medium may be any non-transitory medium that can contain, or store a program for use by or in connection with an instruction execution system, apparatus, or device.

The system (100) includes a printer cartridge (114) that includes a printhead (116) and a fluid supply (112). The printer cartridge (114) may be removable from the system (100) for example, as a replaceable printer cartridge (114).

The printer cartridge (114) includes a printhead (116) that ejects drops of fluid through a plurality of nozzles (124) towards a print medium (126). The print medium (126) may be any type of suitable sheet or roll material, such as paper, card stock, transparencies, polyester, plywood, foam board, fabric, canvas, and the like. In another example, the print medium (126) may be an edible substrate. In yet one more example, the print medium (126) may be a medicinal pill.

Nozzles (124) may be arranged in columns or arrays such that properly sequenced ejection of fluid from the nozzles (124) causes characters, symbols, and/or other graphics or images to be printed on the print medium (126) as the printhead (116) and print medium (126) are moved relative to each other. In one example, the number of nozzles (124) fired may be a number less than the total number of nozzles (124) available and defined on the printhead (116).

The printer cartridge (114) also includes a fluid supply (112) to supply an amount of fluid to the printhead (116). In general, fluid flows between the fluid supply (112) and the printhead (116). In some examples, a portion of the fluid supplied to the printhead (116) is consumed during operation and fluid not consumed during printing is returned to the fluid supply (112).

In some examples, a mounting assembly positions the printhead (116) relative to a media transport assembly, and media transport assembly positioning the print medium (126) relative to printhead (116). Thus, a print zone (128), indicated by the dashed box, is defined adjacent to the nozzles (124) in an area between the printhead (116) and the print medium (126). In one example, the printhead (116) is a scanning type printhead (116). As such, the mounting assembly includes a carriage for moving the printhead (116) relative to the media transport assembly to scan the print medium (126). In another example, the printhead (116) is a non-scanning type printhead (116). As such, the mounting assembly fixes the printhead (116) at a prescribed position relative to the media transport assembly. Thus, the media transport assembly positions the print medium (126) relative to the printhead (116).

The printhead (116) also includes a metal-etched EPROM array (134). In other words, the printhead (116) may include an EPROM array (134) that includes a number of EPROM cells having etched multi-metal floating gates. A metal-etched EPROM array (134) may be used to store data. For example, each EPROM cell initially may have all gates, i.e., the control gate and floating gate, open putting each EPROM cell in the array (134) in a low resistance state. To program an EPROM cell of the EPROM array (134), or to change the state of the EPROM cell for example to a h resistance state, a programming voltage is applied to a control gate and drain of the EPROM cell while a source and substrate of the EPROM are held at ground. This programming voltage draws electrons train the drain to the floating gate through hot carrier injection. The excited electrons are pushed through and trapped on the other side of the dielectric layer, giving the floating gate a more negative charge, thereby increasing the effective threshold voltage of the floating gate of the EPROM cell. The threshold voltage referring to a minimum voltage to turn on the transistor or the EPROM cell. During use of the EPROM cell, a cell impedance measurement unit monitors the resistance of the EPROM cell, the EPROM cell resistance is the EPROM is determined to be in a first state (or pre-programmed state) associated with a first logic value, if the cell resistance is the cell is determined to be in a second state (or programmed state) associated with a second logic value. Accordingly, a string of programmed and un-programmed EPROM cells in an EPROM array (134) form a string of ones and zeros which are used to represent data stored in the printhead (116).

During reading, a single EPROM cell in an EPROM array (134) may be identified. In this example each EPROM cell is connected to a column select transistor and a row select transistor for multiplexing. When both transistors are turned on, then the EPROM cell is selected. The select transistors are controlled by multiplexing signals.

The EPROM array (134) may be an EPROM array (134) meaning that the EPROM array (134) is formed of EPROM cells having etched multi-metal floating gates. For example, a multi-metal layer of the floating gate of EPROM cell may include two layers. In a first etch, a number of sides of both layers may be etched. In a subsequent etch, the top layer may be etched to expose the underlying layer. From this underlying layer, a dielectric that is between the control gate and the floating gate may be formed. An EPROM cell having an etched multi-metal floating gate may expose a material that is more desirable to generate the dielectric between the control gate and the floating gate. For example, previously dielectric layers grown from the EPROM floating gate have been thick. However, by exposing the underlying second layer via etching, a thinner dielectric between the control gate and the floating gate may be formed, which dielectric may be tantalum aluminum oxide.

As will be described below, the metal-etched EPROM array (134) may be used to store any type of data. Examples of data that may be stored in the metal-etched EPROM array (134) include fluid supply specific data and/or fluid identification data, fluid characterization data, fluid usage data, printhead (116) specific data, printhead (116) identification data, warranty data, printhead (116) characterization data, printhead (116) usage data, authentication data, security data, Anti-Counterfeiting data (ACF), ink drop weight, firing frequency, initial printing position, acceleration information, and gyro information, among other forms of data. In a number of examples, the metal-etched EPROM array (134) is written at the time of manufacturing and/or during the operation of the printer cartridge (114). The data stored by it may provide information to the controller to adjust the operation of the printer and ensure correct operation.

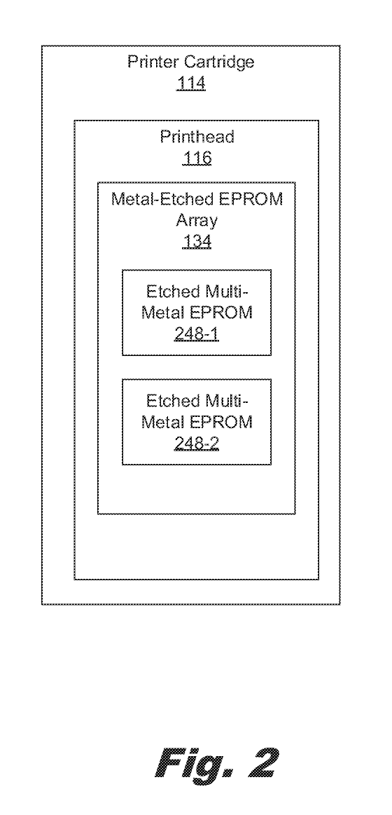

FIG. 2 is a block diagram of a printer cartridge (114) that uses a printhead (116) with a number of erasable programmable read only memory (EPROM) cells (248) having etched multi-metal floating gates according to one example of the principles described herein. In some examples, the printer cartridge (114) includes a printhead (116) that carries out at least a part of the functionality of the printer cartridge (114). For example, the printhead (116) may include a number of nozzles (FIG. 1, 124). The printhead (116) ejects drops of fluid from the nozzles (FIG. 1, 124) onto a print medium (FIG. 1, 126) in accordance with a received print job. The printhead (116) may also include other circuitry to carry out various functions related to printing. In some examples, the printhead (116) is part of a larger system such as an integrated printhead (IPH). The printhead (116) may be of varying types. For example, the printhead (116) may be a thermal inkjet (TIJ) printhead or a piezoelectric inkjet (PIJ) printhead, among other types of printhead (116).

The printhead (116) includes an etched multi-metal EPROM array (134) to store information relating to at least one of the printer cartridge (114) and the printhead (116). In some examples, the EPROM array (134) includes a number of EPROM cells (248-1, 248-2) having etched multi-metal floating gates formed in the printhead (116). In other words a floating gate of the EPROM cell may be formed of a top layer that is etched to expose an underlying layer, which produces a higher capacitive dielectric layer. To store information, an EPROM cell (248) may be set to a particular logic value.

As will be described below, an EPROM cell (248) includes a control gate, a floating gate, and a semiconductor substrate. The control gate and the floating gate are capacitively coupled to one another with a dielectric material between them such that the control gate voltage is coupled to the floating gate. Another layer of dielectric material is also disposed between the floating gate and the semiconductor substrate.

A metal-etched EPROM array (134) may store information by setting a number of etched multi-metal EPROM cells (248), to different logic values. Setting an etched multi-metal EPROM cell (248) to a value other than its initial value may be referred to as programming the etched multi-metal EPROM cell (248). During programming, a high voltage bias on the drain of the etched multi-metal EPROM cell (248) generates energetic “hot” electrons. A positive voltage bias between the control gate and the drain pulls some of these hot electrons onto the floating gate. As electrons are pulled onto the floating gate, for example through Fowler-Nordheirn (FN) tunneling, the threshold voltage of the etched multi-metal EPROM cell (248), that is, the voltage used to regulate the gate/drain to conduct current, increases. If sufficient electrons are pulled onto the floating gate, the effective cell threshold voltage will increase. As a result, for a given gate and drain bias voltage, the source-to-drain current will be reduced or suspended. This will cause the etched multi-metal EPROM cell (248) to block current at voltage level, which changes the operating state of the etched multi-metal EPROM cell (48) from a low resistance state to a high resistance state. After programming of the etched multi-metal EPROM cell (248), a cell sensor (not shown) is used during operation to detect the state of the etched multi-metal EPROM cell (248).

A specific numeric example is provided below. In this example. before programming a resistance of an etched multi-metal EPROM cell (248) may be low, for example approximately 3,000 Ohms. During programming a positive bias is applied to the gate and drain of the etched multi-metal EPROM cell (248) such that a potential is created between the drain and the control gate. The positive bias applied to the drain and gate may be near breakdown levels, such as between 12-16 volts. At the same time, the source and a substrate in which the source and drain are disposed may be set to ground. The positive voltage difference between the source and the drain draws electrons towards the drain. This large positive potential excites electrons and when the electrons have sufficient energy, pulls electrons from the drain to the floating gate through hot carrier injection, giving the floating gate a more negative charge, thereby increasing the effective threshold voltage of the floating gate.

The threshold voltage of the floating date is a voltage to turn on the transistor or the EPROM cell. Accordingly, in some examples enough electrons may be passed to the floating gate to increase its resistance, for example to 5,000 Ohms. In other words, the trapped electrons may cause a threshold voltage of approximately −5 V. Accordingly, when a signal of 5 V is applied to the control gate, no channel would be formed in the floating gate, thus increasing the resistance, which difference in resistance can be read by a controller (FIG. 1, 106) to determine a logical value of the etched multi-metal EPROM cell (248). Accordingly, the resistance, and corresponding logical value of the EPROM cell (248) relies on the threshold voltage of the floating gate.

The number of etched multi-metal EPROM cells (248) may be grouped together into an etched multi-metal EPROM array (134). In some examples, the etched multi-metal EPROM array (134) may be a cross bar array. In this example, etched multi-metal EPROM cells (248) may be formed at an intersection of a first set of elements and a second set of elements, the elements forming a grid of intersecting nodes, each node defining an etched multi-metal EPROM cell (248).

The etched multi-metal EPROM array (134) may be used to store any type of data. Examples of data that may be stored in the etched metal EPROM array (134) include fluid supply specific data and/or fluid identification data, fluid characterization data, fluid usage data, printhead (116) specific data, printhead (116) identification data, warranty data, printhead (116) characterization data, printhead (116) usage data, authentication data, security data, Anti-Counterfeiting data (ACF), ink drop weight, firing frequency, initial printing, position, acceleration information, and gyro information, among other forms of data. In a number of examples, the etched multi-metal EPROM array (134) is written at the time of manufacturing and/or during the operation of the printer cartridge (114).

In some examples, the printer cartridge (114) may be coupled to a controller (FIG. 1, 106) that is disposed within the system (100). The controller (FIG. 1, 106) receives a control signal from an external computing device (FIG. 1, 102). The controller (FIG. 1, 106) may be an application-specific integrated circuit (ASIC) found on a printer. A computing device (FIG. 1, 102) may send a print job to the printer cartridge (114), the print job being made up of text, images, or combinations thereof to be printed. The controller (FIG. 1, 106) may facilitate storing information to the EPROM array (134). Specifically, the controller (FIG. 1, 106) may pass at least one control signal to the number of etched multi-metal EPROM cells (248). For example, the controller (FIG. 1, 106) may be coupled to the printhead (116), via a control line such as an identification line. Via the identification line, the controller (FIG. 1, 106) may change the logic state of etched multi-metal EPROM cells (248) in the etched multi-metal EPROM array (134) to effectively store information to an etched multi-metal EPROM array (134). For example, the controller (106) may send data such as authentication data, security data, and print job data, in addition to other types of data to the printhead (116) to be stored on the etched multi-metal EPROM array (134).

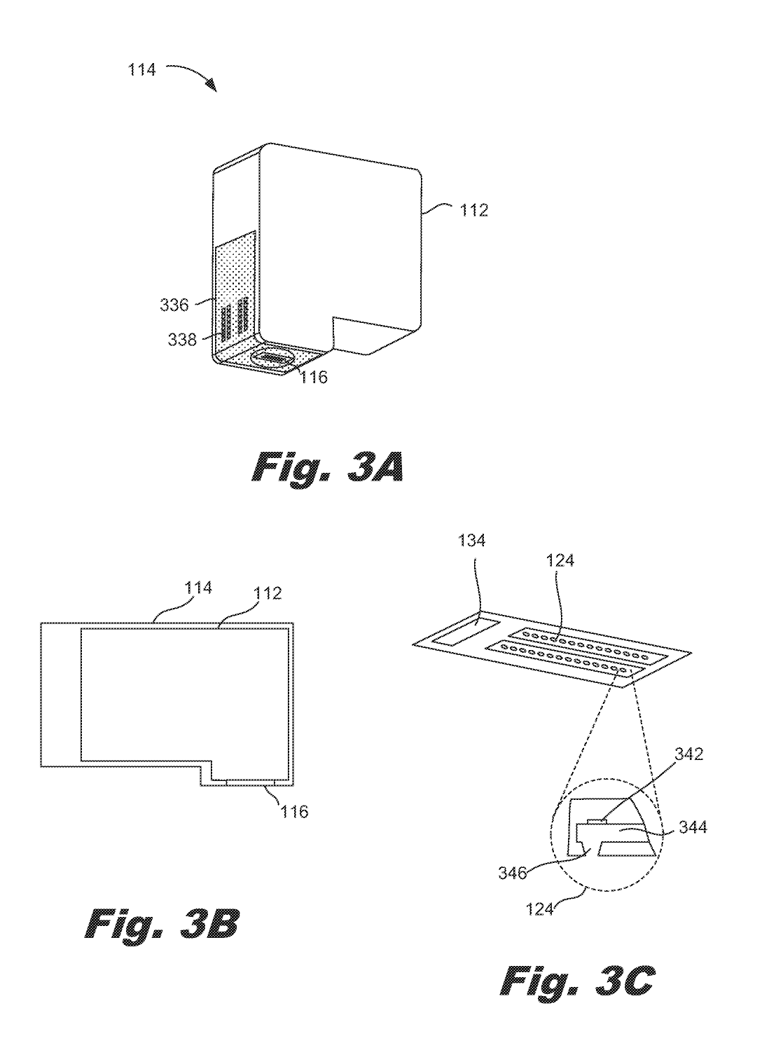

FIGS. 3A and 3B are diagrams of a printer cartridge (114) with a number of EPROM cells (FIG. 2, 248) having etched multi-metal floating gates according to one example of the principles described herein. As discussed above, the printhead (116) may include a number of nozzles (124). In some examples, the printhead (116) may be broken up into a number of print dies with each die having a number of nozzles (124). The printhead (116) may be any type of printhead (116) including, for example, a printhead (116) as described in FIGS. 3A-3C. The examples shown in FIGS. 3A-3C are not meant to limit the present description. Instead, various types of printheads (116) may be used in conjunction with the principles described herein.

The printer cartridge (114) also includes a fluid reservoir (112), a flexible cable (336) and conductive pads (338). In some examples, the fluid may be ink. For example, the printer cartridge (114) may be an inkjet printer cartridge, the printhead (116) may be an inkjet printhead, and the ink may be inkjet ink.

The metal-etched EPROM array (134) depicted in FIG. 3C may be similar to the metal-etched EPROM array (134) depicted in FIGS. 1 and 2. Specifically, the metal-etched EPROM array (134) may include EPROM cells (FIG. 2, 248) having etched multi-metal floating gates. The flexible cable (336) is adhered to two sides of the printer cartridge (114) and contains traces that electrically connect the metal-etched EPROM array (134) and printhead (116) with the conductive pads.

The printer cartridge (114) may be installed into a cradle that is integral to the carriage of a printer. When the printer cartridge (114) is correctly installed, the conductive pads (338) are pressed against corresponding electrical contacts in the cradle, allowing the printer to communicate with, and control the electrical functions of, the printer cartridge (114). For example, the conductive pads (338) allow the printer to access and write to the meta etched EPROM array (134).

The metal-etched EPROM array (134) may contain a variety of information including the type of printer cartridge (114), the kind of fluid contained in the printer cartridge (114), an estimate of the amount of fluid remaining in the fluid reservoir (112), calibration data, error information, and other data. In one example, the metal-etched EPROM array (134) may include information regarding when the printer cartridge (114) should be maintained,

To create an image, the system (FIG. 1, 100) moves the carriage containing the printer cartridge (114) over a print medium (FIG. 1, 126). At appropriate times, the system (FIG. 1, 100) sends electrical signals to the printer cartridge (114) via the electrical contacts in the cradle. The electrical signals pass through the conductive pads (338) and are routed through the flexible cable (336) to the printhead (116). The printhead (116) then ejects a small droplet of fluid from the reservoir (112) onto the surface of the print medium (FIG. 1, 126). These droplets combine to form an image on the surface of the print medium (FIG. 1, 126).

FIG. 3C is a cross sectional diagram of a printhead (116) with a number of EPROM cells (248) having etched multi-metal floating gates according to one example of the principles described herein. More specifically, as depicted in FIG. 3A, the flexible substrate (336) may include a printhead (116) that includes a metal-etched EPROM array (134) that includes a number of EPROM cells (FIG. 2, 248) having etched multi-metal floating gates as described herein. The printhead (116) may also include a number of components for depositing a fluid onto a print medium (FIG. 1, 126). For example, the printhead (116) may include a number of nozzles (124). For simplicity, FIG. 30 details a single nozzle (124); however a number of nozzles (124) are present on the printhead (116). The printhead (116) may include any number of nozzles (124). In an example where the fluid is an ink, a first subset of nozzles (124) may eject a first color of ink while a second subset of nozzles (124) may eject a second color of ink. Additional groups of nozzles (124) may be reserved for additional colors of ink.

A nozzle (124) may include an ejector (342), a firing chamber (344), and an opening (346). The opening (346) may allow fluid, such as ink, to be deposited onto a surface, such as a print medium (FIG. 1, 126). The firing chamber (344) may include a small amount of fluid. The ejector (342) may be a mechanism for ejecting fluid through an opening (346) from a firing chamber (344), where the ejector (342) may include a firing resistor or other thermal device, a piezoelectric element, or other mechanism for ejecting fluid from the firing chamber (344).

For example, the ejector (342) may be a firing resistor. The firing resistor heats up in response to an applied voltage. As the firing resistor heats up, a portion of the fluid in the firing chamber (344) vaporizes to form a bubble. This bubble pushes liquid fluid out the opening (346) and onto the print medium (FIG. 1, 126). As the vaporized fluid bubble pops, a vacuum pressure within the firing chamber (344) draws fluid into the firing chamber (344) from the fluid supply (112), and the process repeats. In this example, the printhead (116) may be a thermal inkjet printhead.

In another example, the ejector (342) may be a piezoelectric device. As a voltage is applied, the piezoelectric device changes shape which generates a pressure pulse in the firing chamber (344) that pushes a fluid out the opening (346) and onto the print medium (FIG. 1, 126). In this example, the printhead (116) may be a piezoelectric inkjet printhead.

The printhead (116) and printer cartridge (114) may also include other components to carry out various functions related to printing. For simplicity, in FIGS. 3A-30, a number of these components and circuitry included in the printhead (116) and printer cartridge (114) are not indicated; however such components may be present in the printhead (116) and printer cartridge (114). In some examples, the printer cartridge (114) is removable from a printing system for example, as a disposable printer cartridge,

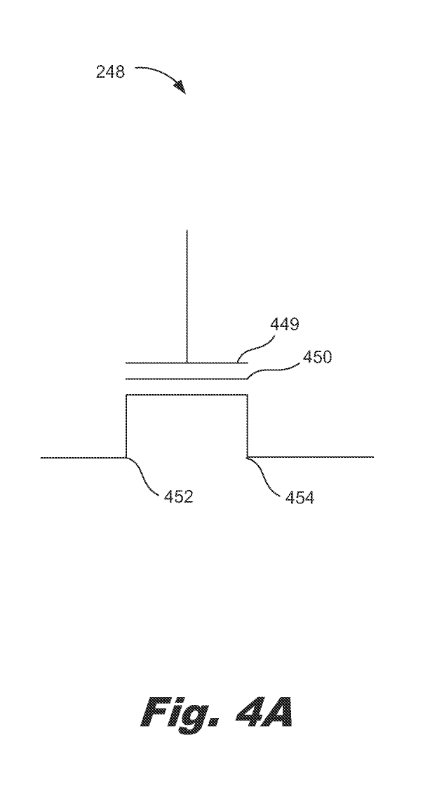

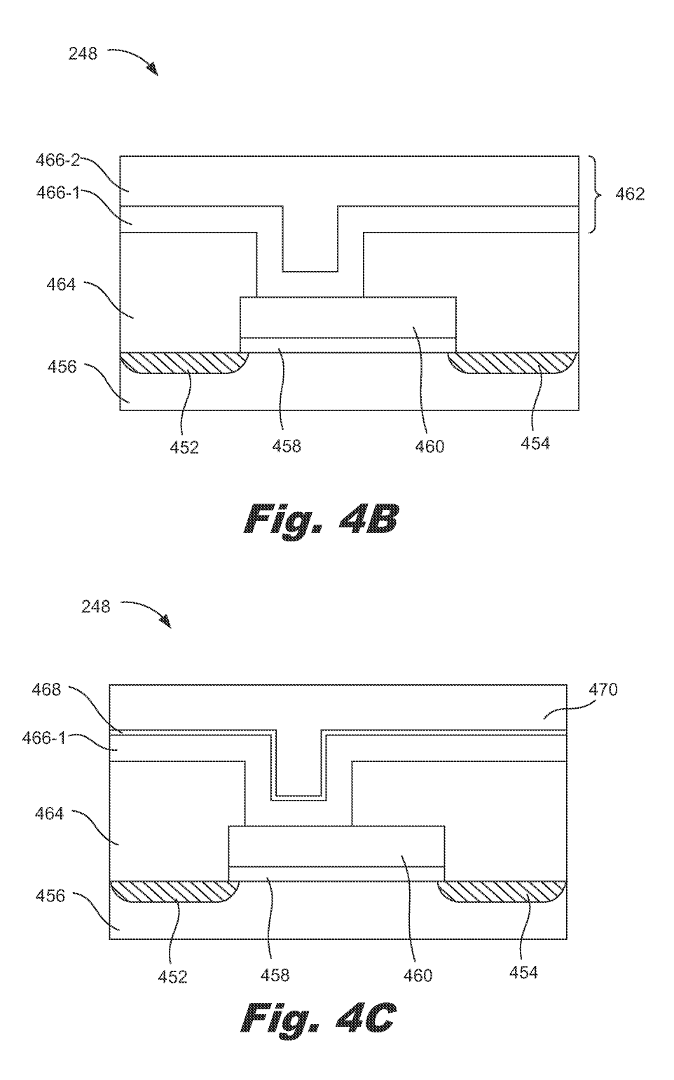

FIGS. 4A-4C are diagrams of an EPROM cells (248) having multi-metal etched floating gates according to one example of the principles described herein. Specifically, FIG. 4A is a circuit diagram of an etched multi-metal EPROM cell (248) and FIGS. 4B and 40 are cross-sectional diagrams of the layers of an etched multi-metal EPROM cell (248), FIG. 4B being a pre-etch cross-sectional diagram and FIG. 40 being a post-etch, or operational, cross-sectional diagram.

The etched multi-metal EPROM cell (248) includes a control gate (449), a floating gate (450), a source (452) and a drain (454). In some examples, the source (452) and the drain (454) may be formed in a substrate (456). In some examples, the substrate (456) maybe an n-type substrate (456) with p-doped portions forming the source (452) and drain (454). In other examples, the substrate (456) may be a p-type substrate (456) with n-doped portions forming the source (452) and the drain (454).

The floating gate (450) of the EPROM cell (248) may be separated from the substrate (456) by a first dielectric layer (458). The first dielectric layer (458) may be a gate oxide that electrically isolates the floating gate (450) from the source (452) and the drain (454). In some examples, the first dielectric layer (458) may be silicon dioxide, silicon carbide, and silicon nitride among other dielectric materials.

In some examples, the floating gate (450) of the EPROM cell (248) may be formed by a polysilicon layer (460) and a multi-metal layer (462) that is electrically coupled to the polysilicon layer (460). The multi-metal layer (462) may be formed of a number of materials that may be deposited as different sub-layers. For example, the multi-metal layer (462) may include layers of an aluminum copper alloy, an aluminum copper silicon alloy, and a tantalum aluminum alloy with an aluminum copper alloy, among other materials. The layering of the substrate (456), the first dielectric layer (458) and polysilicon layer (460) can be depicted in a circuit as a capacitor as detailed in FIG. 4A. In some examples, during formation, the polysilicon layer (460) may initially be separated from the multi-metal layer (462) by a third dielectric layer (464). The multi-metal layer (462) may contact the polysilicon layer (460) via a gap in the third dielectric layer (464).

As described, the floating gate (450) of the EPROM cell (248) may be formed from the multi-metal layer (462) and a polysilicon layer (460) that may be electrically coupled to one another through a gap in a third dielectric layer (464). The third dielectric layer (464) may be formed from phosphosilicate glass (PSG), borophosphosilicate glass (BPSG) and/or undoped silicate glass (USG), among other dielectric materials, The first dielectric layer (458) between the polysilicon layer (460) and the substrate (456) creates a capacitive coupling between the polysilicon layer (460) and the substrate (456).

The multi-metal layer (462) of the floating gate (450) may be a metal etched layer. For example, the multi-metal layer (462) may include a number of sub-layers (466). Specifically, an underlying, or first, sub-layer (466-1) and an upper, or second sub-layer (466-2). The different sub-layers (466) may be formed of different materials. For example, the first sublayer (466-1) may be formed of a material that more easily oxidizes, or that oxidizes into a material having a greater dielectric coefficient.

For example, the first sublayer (466-1) may be formed of a tantalum aluminum alloy and the second sublayer (466-2) may be formed of an aluminum alloy that may include a small portion of copper. For example, the aluminum copper alloy may include 98-99.5 percent by atomic weight of aluminum and 0.5 to 1.0 percent by atomic weight of copper. Aluminum is a self-passivating metal, i.e., aluminum tends to form a passivated aluminum oxide layer having a thickness of about 30-40 Angstrom units (A) on its surface, which then blocks the oxygen diffusion from the surface and protects the underlying aluminum metal from further oxidation. As a result, a sufficient thickness of aluminum oxide may not be formed for it to act as an active layer despite treatment under high temperature and/or pressure conditions, such as by furnace oxidation or plasma oxidation or sputter deposition. The tantalum aluminum alloy on the other hand may oxidize more easily and form a more capacitive layer for a given thickness. In other words, the tantalum aluminum oxide may be thinner as compared to an aluminum oxide, all while maintaining at least as great a capacitance as the aluminum oxide, Put yet another way, the tantalum aluminum alloy may be able to oxidize to a greater thickness than the aluminum alloy and oxidizing to form a compound having a higher dielectric constant. The enhanced oxidizing characteristics of the first sublayer (466-1) material may allow for greater control over the EPROM cell (248) formation. For example, with greater thicknesses and higher dielectric constants available, more options are possible with regards to setting desired capacitances of the different gates of the etched multi-metal EPROM cell (248) which capacitances effect resistance levels and logic levels of the etched multi-metal EPROM cell (248).

First both the first sublayer (466-1) and the second sublayer (466-2) may be subject to a dry etch process to remove material from both the first sublayer (466-1) and the second sublayer (466-2), Subsequently, the multi-metal layer (462) may be etched so as to remove the second sublayer (466-2) while preserving the underlying first sublayer (466-1) as depicted in FIG. 40. In other words, the second etch may be a process, such as a wet etch, that removes material from the second sublayer (466-2) which may be an aluminum alloy, but does not remove material from the first sublayer (466-1), which may be a tantalum aluminum alloy, The second sublayer (466-2) may be formed and then removed simultaneously with a forming operation of other components of a printhead (FIG. 1, 116).

Prior to etching, as depicted in FIG. 4B, the upper second sub-layer (466-2) may cover the entire surface of the underlying first sub-layer (466-1). After etching, as depicted in FIG. 40, the second sublayer (466-2) has been removed via the metal etching to expose a portion of the first sublayer (466-1). From this first, underlying layer (466-1) a second dielectric layer (468) may be formed. For example, via a physical vapor oxidation or thermal oxidation process, the second dielectric layer (468) may be grown from the first sublayer (466-1) of the multi-metal layer (462) of the floating gate (450). The second dielectric layer (468) may separate the control gate (449), which may be formed of a control gate metallic layer (470), from the multi-metal layer (462) of the floating gate (450).

As described above, the second dielectric layer (468) may be formed by oxidation of the exposed portion of the first sublayer (466-1). In some examples, the first sublayer (466-1) material may be selected to reduce the thickness of the second dielectric layer (468). For example, the first sublayer (466-1) may be a tantalum aluminum alloy. Oxidizing the tantalum aluminum alloy first sublayer (466-1) may result in a tantalum aluminum oxide second dielectric layer (468), which may be thinner than otherwise possible. For example, the second dielectric layer (468) may be less than 100 nanometers thick, for example between 5 and 15 nanometers thick.

The second dielectric layer (468) between the control gate metallic layer (470) of the control gate (449) and the first sublayer (466-1) of the floating gate (450) creates a capacitive coupling between the control gate metallic layer (470) and the first sublayer (466-1). In other words, the control gate metallic layer (470) forms the control gate (449) and the 1) the first sublayer (466-1) and the 2) polysilicon layer (460) form the floating gate (450) of the etched multi-metal EPROM cell (248), with the second dielectric layer (468) and first dielectric layer (458) respectively forming a capacitive coupling between the corresponding layers.

Including a second dielectric layer (468) formed from an exposed first sublayer (466-1) of a metal-etched multi-metal layer (462) may allow for a thinner EPROM cell (248) by reducing the size of the second dielectric layer (468) while preserving a desired capacitance of the etched multi-metal EPROM cell (248). For example, by exposing the first sublayer (466-1) which may be a material that is oxidized to form a dielectric layer with a higher capacitance, less of the second dielectric layer (468) is used to generate a desired capacitance. The reduced amount of material used in the second dielectric layer (468) reduces the overall size of the etched multi-metal EPROM cell (248) while maintaining a desired capacitance of the etched multi-metal EPROM cell (248).

The increased capacitance of the etched multi-metal EPROM cell (248) increases the efficiency of the etched multi-metal EPROM cell (248). For example, as described above, the resistance of the etched multi-metal EPROM cell (248), and corresponding logic value, is dependent upon the voltage at the floating gate (450). The voltage at the floating gate (450) is dependent at least in part, upon the capacitance of the control gate (449), a larger capacitance at the control gate (449) being desired so as to yield a more clear distinction between states of the etched multi-metal EPROM cell (248). Accordingly, using a material with a smaller dielectric constant may necessitate a larger dielectric to achieve the desired capacitance at the control gate (449), In other words, the high dielectric constant second dielectric layer (468) of the present specification may allow for a thinner second dielectric layer (466) than would otherwise be possible while maintaining a desired capacitance. For example, the second dielectric layer (466) may be between 2 and 100 nanometers thick while maintaining a capacitance of at least 0.15 picofarads. As described above, using a second dielectric layer (468) formed of an etched multi-metal layer (462), a smaller EPROM cell (248) for a given capacitance may be formed.

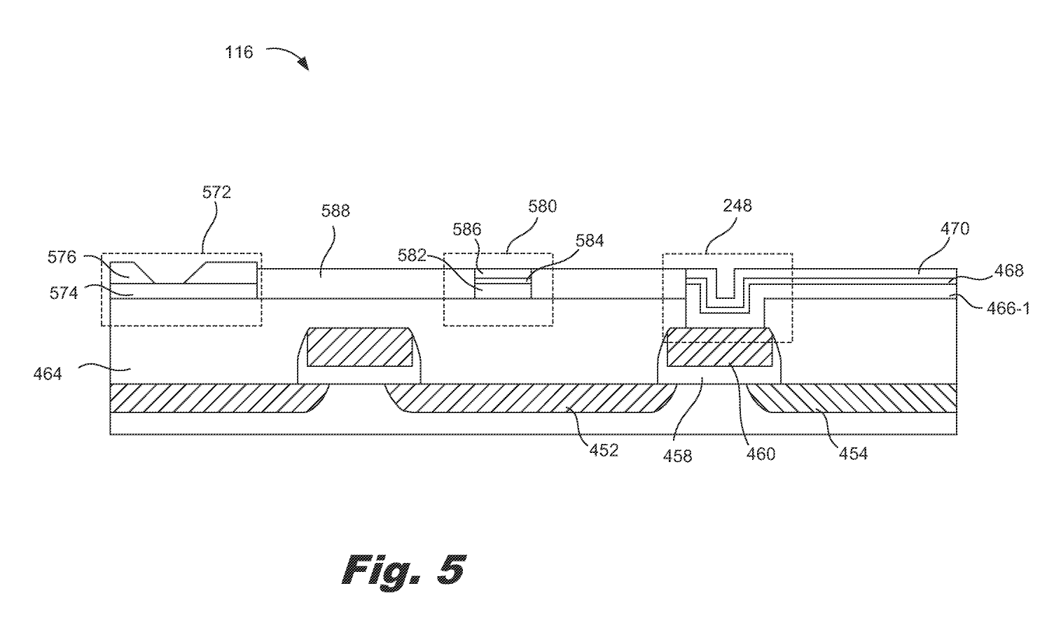

FIG. 5 is a cross-sectional view of a printhead (116) including an EPROM cell (248) having etched multi-metal floating gates, a memristor (580), and a firing resistor (572) according to one example of the principles described herein. As described above, the printhead (116) may include an etched multi-metal EPROM cell (248) that includes a source (452) and a drain (454). The source (452) and drain (454) may be separated from the polysilicon layer (460) by a first dielectric layer (458).

As described above, the etched multi-metal EPROM cell (248) also includes a multi-metal layer (FIG. 4, 462) that includes a first sublayer (466-1) and a second sublayer (FIG. 4, 466-2), a second dielectric layer (468), and a control gate metallic layer (470). In some examples, a number of these layers may have the same material properties, or be the same material as other components in the printhead (116). For example, the printhead (116) may include a memristor (580) that includes a first electrode (582), a switching oxide (584) disposed on top of the first electrode (582), and a second electrode (586) disposed on top of the switching oxide (584). Similarly, the printhead (116) may include an ejector such as a firing resistor (572) that includes a first layer (574) and a second layer (576).

In some examples, the different layers of the memristor (580) and firing resistor (572) may correspond, at least in part to the layers of the etched multi-metal EPROM cell (248). For example, at least one of the bottom electrode (582) of the memristor (580) and the first layer (574) of the firing resistor (572) may be made of the same material, and in some cases the same layer of the same material, as the first sublayer (466-1) of the EPROM cell (248). For example, the first layer (574) of the firing resistor (572), the bottom electrode (582) of the memristor (580), and the first sublayer (466-1) of the EPROM cell (248) may be formed of a tantalum aluminum alloy and may be formed in the same layer at the same time as one another.

Still further, the second layer (576) of the firing resistor (572) may be of the same material, and in some cases the same layer of the same material, as the second sublayer (FIG. 4, 466-2) of the EPROM cell (248). In other words, as material making up the second sublayer (FIG. 4, 466-2) is etched to expose the first sublayer (466-1) as described above; the same material, which may be an aluminum copper alloy or other aluminum alloy, may be etched to remove a portion of the second layer (576) of the firing resistor (572) to expose a portion of the first layer (574) of the firing resistor (572). In other words, the metal etching used to expose the first sublayer (466-1) of the EPROM cell (248) may be the same metal etching process used to expose a first layer (574) of the firing resistor (572). Accordingly, as demonstrated co-utilizing these layers may take advantage of processes (i.e., etching) used to form other components such as the firing resistors (572).

Similarly, the switching oxide (584) of the memristor (580) may be the same material, and in some cases the same layer of the same material, as the second sublayer (466-2) of the etched multi-metal EPROM cell (248). For example, both the switching oxide (584) of the memristor (580 and the second dielectric layer (468) of the etched multi-metal EPROM cell (248) may be formed by oxidizing an adjacent layer. More specifically, the first sublayer (466-1) which may be a tantalum aluminum alloy, and the bottom electrode (582), which may also be the same tantalum aluminum alloy, may both be oxidized to form the second dielectric layer (468) and the switching oxide (584), respectively. In other words, the second dielectric layer (468) and the switching oxide (584) may be formed as the same layer at the same time as one another.

Still further, the top electrode (586) may be the same material, and in some examples formed of the same layer as the control gate metallic layer (470) of the EPROM cell (248). The printhead (116) may also include a passivation layer (588) that may be from 3,000 to 6,000 Angstroms thick, While the different components may share a printhead (116), the components may be associated with different resistors. For example, a first transistor corresponding to the gate (460) and the first dielectric layer (462) may be utilized by the EPROM cell (248). This first transistor may be a short-channel transistor with a width between 2.2 and 2.4 microns thick.

By co-utilizing these layers, multiple layers of different components may be formed simultaneously thus reducing the operations to form the components of a printhead (116). Moreover, as the layers used to form the etched multi-metal EPROM cell (248) may be presently used for other components such as the memristor (580) and firing resistor (572), the etched multi-metal EPROM cells (248) may be formed without additional manufacturing equipment or processes.

An etched multi-metal EPROM cell (248) may be beneficial in that it, by exposing the first sublayer (466-1) which is formed of a metal that is more easily oxidized, a thinner EPROM cell (248) may be used. Moreover, it may make use of processes and layering that are already present on the printhead (116), thus avoiding new process operations and new manufacturing equipment.

Certain examples of the present disclosure are directed to a printer cartridge (FIG. 1, 114) and printhead (FIG. 1, 116) with a number of etched multi-metal EPROM cells (FIG. 2, 248) that provide a number of advantages not previously offered including, creating an EPROM memory device that is compact and has a high capacitance which leads to an improved flexibility in memory device design; reducing the footprint of an EPROM cell (248) so as to free up valuable silicon space for other components or more memory; and increasing flexibility in printhead (116) memory design; all while avoiding additional manufacturing processes and equipment. However, it is contemplated that the devices disclosed herein may provide useful in addressing other issues and deficiencies in a number of technical areas. Therefore the systems and methods disclosed herein should not be construed as addressing any of the particular issues described herein.

The preceding description has been presented to illustrate and describe examples of the principles described. This description is not intended to be exhaustive or to limit these principles to any precise form disclosed. Many modifications and variations are possible in light of the above teaching.

What is claimed is:

1. A printhead with a number of erasable programmable read only memory (EPROM) cells, the printhead comprising:
a number of nozzles to deposit an amount of fluid onto a print medium, each nozzle comprising:
a firing chamber to hold the amount of fluid;
an opening to dispense the amount of fluid onto the print medium; and
an ejector to eject the amount of fluid through the opening; and
a number of EPROM cells, each EPROM cell comprising:
a substrate having a source and a drain disposed therein;
a floating gate separated from the substrate by a first dielectric layer, in which:
the floating gate comprises a multi-metal layer; and
the multi-metal layer is a metal etched layer; and
a control gate separated from the multi-metal layer of the floating gate by a second dielectric layer,

2. The printhead of claim 1, in which the fluid is inkjet ink.

3. The printhead of claim 1, in which the floating gate further comprises a polysilicon layer electrically coupled to the multi-metal layer.

4. The printhead of claim 1, in which the multi-metal layer comprises a first sub-layer disposed underneath a second sub-layer, in which a portion of the second sub-layer is etched to expose a portion of the first sub-layer.

5. The printhead of claim 4, in which the second dielectric layer is formed by oxidation of the exposed portion of the first sub-layer.

6. The printhead of claim 4, in which:
the first sub-layer is a tantalum aluminum alloy; and
the second sub-layer is an aluminum alloy.

7. The printhead of claim 1, in which the second dielectric layer is between 2 and 100 nanometers thick.

8. The printhead of claim 1, in which the number of EPROM cells are disposed in rows and columns in an EPROM array.

9. A printer cartridge having a number of programmable read only memory (EPROM) cells, the cartridge comprising:
a fluid supply; and
a printhead to deposit fluid from the fluid supply onto a print medium, the printhead comprising:
a number of EPROM cells, each EPROM cell comprising:
a substrate having a source and a drain disposed therein;
a floating gate separated from the substrate by a first dielectric layer, the floating gate comprising:
a polysilicon layer separated from the substrate by a first dielectric layer; and
a multi-metal layer separated from the polysilicon layer by a third dielectric layer; in which:
the multi-metal layer contacts the polysilicon layer through a gap in the third dielectric layer; and
the multi-metal layer is a metal etched structure; and
a control gate separated from the substrate by a second dielectric layer, in which the second dielectric layer is formed from oxidation of one sub-layer of the multi-metal layer.

10. The cartridge of claim 9, in which:
the fluid is inkjet ink;
the printer cartridge is an inkjet printer cartridge; and
the printhead is an inkjet printhead.

11. The cartridge of claim 9, in which the second dielectric: layer comprises tantalum aluminum oxide.

12. The cartridge of claim 9, in which:
the multi-metal layer comprises a first sub-layer disposed underneath a second sub-layer; and
the multi-metal layer is etched such that a portion of the second sub-layer is etched while retaining the first sub-layer.

13. The cartridge of claim 9, in which:
the printhead comprises an ejector to eject the fluid; and
the ejector is formed of the same material as the multi-metal layer of the EPROM cell.

14. The cartridge of claim 13, in which the ejector is formed in a same layer as the multi-metal layer of the EPROM cell.

15. The cartridge of claim 9, in which the gap in the third dielectric layer s filled with the first sub-layer of the multi-metal layer.
